(19) United States
(12) Patent Application Publication
(10) Pub. No.: US 2007/0246787 A1
(43) Pub. Date: Oct. 25, 2007

(54) On-plug magnetic tunnel junction devices based on spin torque transfer switching

(76) Inventors: Lien-Chang Wang, Fremont, CA (US); Eugene Youjun Chen, Fremont, CA (US); Yiming Huai, Pleasanton, CA (US); Zhitao Diao, Fremont, CA (US)

Correspondence Address: FISH & RICHARDSON, PC, P.O. BOX 1022, MINNEAPOLIS, MN, 55440-1022, US

(21) Appl. No.: 11/394,056

(22) Filed: Mar. 29, 2006

(51) Int. Cl. H01L 43/00

(52) U.S. Cl. 257/421

(57) ABSTRACT

Techniques and device designs associated with devices having magnetic or magnetoresistive tunnel junctions (MTJs) configured to operate based on spin torque transfer switching. On-plug MTJ designs and fabrication techniques are described.

### BACKGROUND

This application relates to spin torque transfer magnetic tunnel junction devices.

Various multilayer magnetic materials include at least one ferromagnetic layer configured as a “free” layer whose magnetic direction can be changed by an external magnetic field or a spin-polarized control current. Magnetic memory devices may be constructed using such multilayer structures where information is stored based on the magnetic direction of the free layer.

One example for such a multilayer structure is a magnetic or magnetoresistive tunnel junction (MTJ) which includes at least three layers: two ferromagnetic layers and a thin layer of a non-magnetic insulator as a barrier layer between the two ferromagnetic layers. The insulator material for the middle barrier layer is not electrically conductive and hence functions as a barrier between the two ferromagnetic layers. When the thickness of the insulator is sufficiently thin, e.g., a few nanometers or less, electrons in the two ferromagnetic layers can “penetrate” through the thin layer of the insulator due to a tunneling effect under a bias voltage applied to the two ferromagnetic layers across the barrier layer. The resistance to the electrical current across the MTJ structure varies with the relative direction of the magnetizations in the two ferromagnetic layers. When the magnetizations of the two ferromagnetic layers are parallel to each other, the resistance across the MTJ structure is at a minimum value Rₚ. When the magnetizations of the two ferromagnetic layers are opposite to or anti-parallel with each other, the resistance across the MTJ is at a maximum value R_{AP}. The magnitude of this effect can be characterized by a tunneling magnetoresistance (TMR) defined as (R_{AP}−Rₚ)/Rₚ.

The relationship between the resistance to the current flowing across the MTJ and the relative magnetic direction between the two ferromagnetic layers in the TMR effect can be used for nonvolatile magnetic memory devices to store information in the magnetic state of the MTJ. Magnetic random access memory (MRAM) and other magnetic memory devices based on the TMR effect, for example, may be an alternative to and compete with electronic RAM devices in various applications. In such magnetic memory devices, one ferromagnetic layer is configured to have a fixed magnetic direction and the other ferromagnetic layer is a “free” layer whose magnetic direction can be changed to be either parallel or opposite to the fixed direction. Information is stored based on the relative magnetic direction of the two ferromagnetic layers on two sides of the barrier of the MTJ. For example, binary bits “1” and “0” may be recorded as the parallel and anti-parallel orientations of the two ferromagnetic layers in the MTJ. Recording or writing a bit in the MTJ can be achieved by switching the magnetization direction of the free layer, e.g., by a writing magnetic field generated by supplying currents to write lines disposed in a cross stripe shape, by a current flowing across the MTJ based on the spin torque transfer effect, or by other means.

In the spin torque transfer switching, the current required for changing the magnetization of the free layer can be small (e.g., 0.5 mA or lower in some MTJs) and significantly less than the current used for the field switching. Therefore, the spin torque transfer switching in an MTJ cell can be used to significantly reduce the power consumption of the cell. In addition, conductor wires for carrying currents that generate the sufficient magnetic field for switching the magnetization of the free layer may be eliminated. This allows a spin torque transfer switching MTJ cell to be smaller than a field switching MTJ cell. Accordingly, the MTJ cells for the spin torque transfer switching may be fabricated at a higher areal density on a chip than that of field switching MTJ cells and have potential in high density memory devices and applications.

### SUMMARY

This application describes magnetic or magnetoresistive tunnel junctions (MTJs) and techniques associated with devices having MTJ cells configured to operate based on spin torque transfer switching. On-plug MTJ designs and fabrication techniques are described.

In one implementation, a device is described to include a substrate; a conductive via formed over the substrate and vertically extended substantially perpendicular to the substrate; a metal plug formed on top of the conductive via; a dielectric material embedding the metal plug and exposing a top surface of the metal plug; and a magnetic tunnel junction (MTJ) cell formed on the top surface of the metal plug.

In another implementation, a device is described to include a substrate and a magnetic tunnel junction (MTJ) cell formed over the substrate. The MTJ cell includes a free ferromagnetic layer having a magnetization direction that is changeable between a first direction and a second substantially opposite direction, a fixed ferromagnetic layer having a magnetization direction fixed along substantially the first direction, and an insulator barrier layer formed between the free and fixed ferromagnetic layers to effectuate tunneling of electrons between the free and fixed ferromagnetic layers. The magnetic tunnel junction cell is shaped to be elongated along the first direction. This device also includes a conductor line formed over the substrate and positioned to have a portion which spatially overlaps with the MTJ cell and is parallel to the first direction of the MTJ cell and is electrically coupled to supply a current across the MTJ cell, and a control circuit to control the current to the MTJ cell from the conductor line to change the magnetization direction of the free ferromagnetic layer of the MTJ cell via spin torque transfer.

This application also describes a method for forming an MTJ cell device. This method includes forming a dielectric layer over a substrate; subsequently forming a contiguous metal structure to include at least one metal plug which is embedded in the dielectric layer and a metal layer which is atop and covers a top surface of the dielectric layer; partially removing the metal layer of the contiguous metal structure to leave a remaining metal layer of the metal layer that is atop and covers the top surface of the dielectric layer without exposing the dielectric layer; forming magnetic tunnel junction (MTJ) layers on the remaining metal layer; and patterning the MTJ layers to form at least one MTJ cell on top of the remaining metal layer.

This application further describes another method for forming an MTJ cell device. This method includes forming a dielectric layer over a substrate; subsequently forming at least one metal plug embedded in the dielectric layer; polishing the dielectric layer and the metal plug embedded in the dielectric layer to form a polished surface which exposes a top surface of the metal plug; forming a conductive buffer layer over the polished surface to cover the dielectric layer and the metal plug; forming magnetic tunnel junction (MTJ) layers on the conductive buffer layer; and patterning the MTJ layers to form at least one MTJ cell on the conductive buffer layer and on top of the metal plug.

These and other implementations, their variations and modifications are described in greater detail in the attached drawings, the detailed description, and the claims.

### BRIEF DESCRIPTION OF THE DRAWINGS

FIG. 1 shows one example of an MTJ cell structure.

FIGS. 2 and 3 show an example of a field switching MTJ cell array device and its switching operation.

FIG. 4 shows an example of an MTJ array device where each MTJ cell is formed on top of a metal plug and operated based on spin torque transfer switching.

FIG. 5 shows an example of a spin torque transfer switching MTJ device where each MTJ is formed on top of a respective metal plug and each bit line is oriented to be parallel to a long axis of the MTJ cell to which the bit line supplies a write current.

FIG. 6 compares two on-plug MTJ cell layouts with different orientations for the bit lines for the spin torque transfer switching.

FIG. 7 shows one fabrication process for fabricating on-plug MTJ cells with conductive buffer layer.

FIG. 8 illustrates gaps formed by the polishing step in FIG. 7 at boundaries between metal plugs and inter level dielectric material in which the metal plugs are embedded.

FIG. 9 shows a different fabrication process for forming on-plug MTJ cells using a partial polishing process to eliminate gaps formed at boundaries between metal plugs and inter level dielectric material in which the metal plugs are embedded.

FIG. 10 shows an example of an on-plug MTJ device based on the fabrication process in FIG. 9, where each bit line is oriented to be parallel to a long axis of the MTJ cell to which the bit line supplies a current.

FIG. 11 shows an MTJ device with an MTJ cell array and a circuit that operates the MTJ device based on spin torque transfer switching.

### DETAILED DESCRIPTION

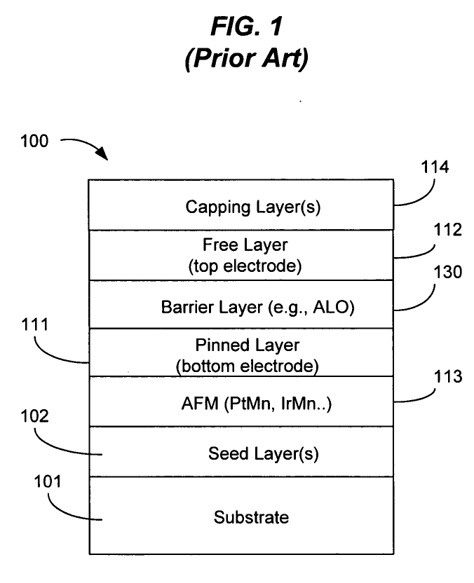

FIG. 1 illustrates an example of an MTJ 100 formed on a substrate 101 of a suitable material such as a Si substrate. The MTJ 100 is constructed on one or more seed layers 102 directly formed on the substrate 101. Over the seed layers 102, an antiferromagnetic (AFM) layer 113 is first formed and then a first ferromagnetic layer 111 is formed on top of the AFM layer 113. After the post annealing, the ferromagnetic layer 111 is then pinned with a fixed magnetization. In implementations, this fixed magnetization may be set to be parallel to the substrate 101 (i.e., the substrate surface). On top of the first ferromagnetic layer 111 is a thin insulator barrier layer 130 such as a metal oxide layer. A second ferromagnetic layer 112 is formed directly on top of the barrier layer 130. In addition, at least one capping layer 114 is formed on top of the second ferromagnetic layer 112 to insulate the MTJ from being exposed to the exterior environment and hence to protect the MTJ.

The magnetization of the ferromagnetic layer 112 is not pinned and can be freely changed to be either parallel to or anti-parallel to the fixed magnetization of the pinned layer 111. For this reason, the ferromagnetic layer 112 is a free layer (FL) and has its magnetic easy axis substantially along the fixed magnetization direction of the pinned layer 111 and its magnetically hard axis substantially perpendicular to the easy axis. The control of the magnetization of the ferromagnetic layer 112 can be through an external write magnetic field in a field switching design, or a write current perpendicularly flowing through the MTJ in a spin torque transfer switching design. A magnetic field in the field operating range, or an applied current across the junction in the current operating range, can force the magnetization of the free layer 112 to be substantially parallel to or substantially opposite to the fixed magnetization of the pinned layer 111. Many magnetic systems have competing energy contributions that prevent a perfect parallel or antiparallel alignment of the magnetic domains or nanomagnets in each ferromagnetic layer. In MTJs, the dominant contribution to the energy state of the nanomagnets within the free layer 112 tends to force the nanomagnets into the parallel or antiparallel alignment, thus producing a substantial parallel or antiparallel alignment. In an actual device, each cell may be elliptically shaped and elongated to provide the shape anisotropy in the magnetic recording layer of the MTJ cell to spatially favor a particular magnetization direction as the easy axis in order to increase the stability of the MTJ cell against perturbations to the magnetization of the MTJ cell, e.g., thermal fluctuation.

In MTJ devices under the field switching design where a write magnetic field is applied to each MTJ cell to write the MTJ cell, each MTJ cell can be positioned at or near the cross point of two separate and mutually orthogonal conductor lines carrying currents. The write magnetic field is jointly generated by the sum of the two magnetic fields that are produced by the currents in the two crossed conductor lines, respectively. This design of using two separate and crossed conductor lines provide a selection mechanism for selecting and addressing MTJ cells for writing data, where the magnetic field from each conductor line alone is controlled to be insufficient to change the magnetization direction of the free layer of an MTJ cell and only provides a half selection for any MTJ cell under its magnetic field. In order to fully select an MTJ cell for switching, the magnetic fields of both crossed conductor lines must be present at a selected MTJ cell at the same time to effectuate the switching of the free layer. In some implementations, the two conductor lines can be configured so that one is located below the MTJ cell and the other is above the MTJ cell. It is also possible to place both conductor lines on one side of the MTJ cell. The two conductor lines sometimes are referred to as a word line (WL) and a bit line (BL). Other terms have also been used for the word line such as the write word line or a digit line. Because these two crossed conductor lines for generating the switching write magnetic field are present and one of the two cross conductor lines is usually placed between the underlying substrate and the MTJ cell layer, each MTJ is usually not directly positioned on top of a metal plug that forms a conductive path for the current flowing through the MTJ but is spatially shifted from the metal plug and is electrically connected to the metal plug via an “in-cell” local interconnecting conductor in an “off-plug” configuration.

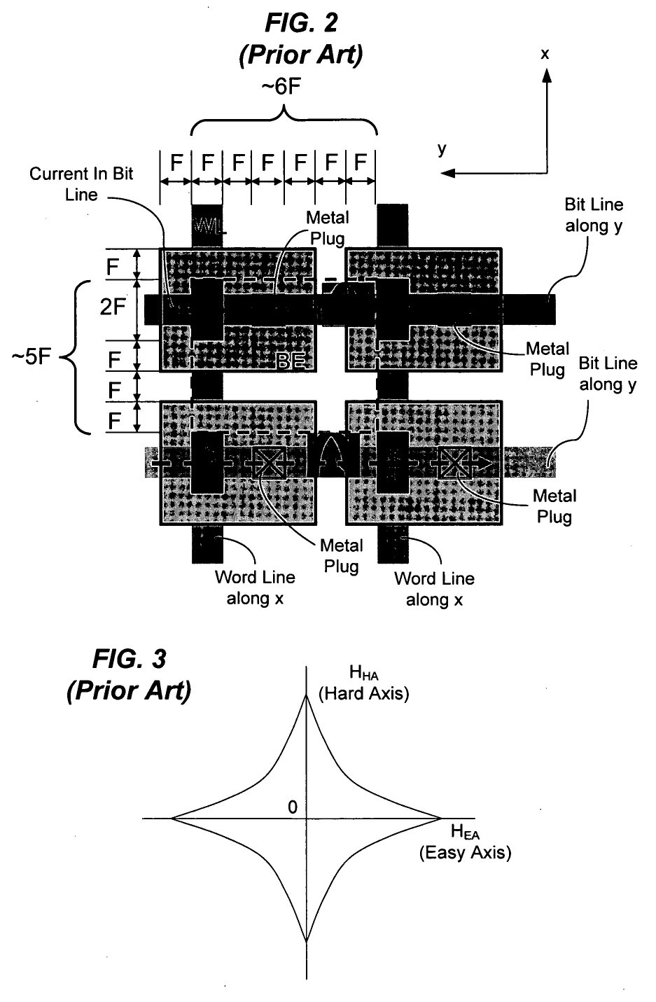

FIG. 2 illustrates one exemplary layout of a unit cell array with MTJ cells in an “off-plug” configuration showing the word lines and bit lines in a field switching MTJ device. Each unit cell includes an MTJ cell and other circuit elements associated with the MTJ cell and thus is bigger than the MTJ cell. Each MTJ cell has an easy axis along the x direction and the bit line and the word line are in the y and x directions, respectively. In this arrangement, the magnetic field generated by the current in the bit line is along the easy axis in the x direction of the MTJ cell as illustrated the arrowed lines in two MTJ cells on the left hand side. The bit lines are located above the MTJ cells. The write word lines are formed between the MTJ cells and the substrate and are shifted laterally from the respective metal plugs. The bottom electrode (BE) strap of each MTJ cell is represented by a rectangular box labeled “BE.” The size of each unit cell is determined by the spatial arrangement of various elements in each cell, including the MTJ cell, the metal plug, the bottom electrode, the bit and word lines and the technology node used in fabrication. For a given technology node used in fabrication, the size of each feature is equal to or greater than the critical dimension F of the technology node used in fabrication and two adjacent features are separated by at least the critical dimension F. Accordingly, a cell design with one transistor per one MTJ cell (1T/1MTJ) has a minimum area for a unit cell of about 30 to 35F² in the example in FIG. 2. Notably, the “off-plug” design in FIG. 2 imposes additional spacing between the separated MTJ cell and the metal plug with other adjacent elements and hence increases the minimum dimension of each unit cell.

FIG. 3 illustrates a relationship between the data write magnetic fields along the easy and hard axes (EA and HA axes) of the free layer of an MTJ cell, respectively, and the switching and non-switching magnetic field phase regions of the MTJ cell. The boundary line between the switching and non-switching magnetic field phase regions is generally an astroid curve symmetrically in the four quadrants of the hard and easy axes of the free layer. When the applied magnetic field lies outside of the astroid curve, the free layer is unstable and can switch with the resultant magnetic field of the two applied magnetic fields by the currents of the word and bit lines. When the applied magnetic field lies inside the astroid curve, the in-plane magnetic coercivity of the free layer dominates and the magnetization direction of the free layer does not change with the magnetic field. The magnetization threshold required for changing the magnetization direction along the magnetization easy axis can be lowered by applying the magnetic field in the direction of the hard axis to the free layer. The write currents in the word and bit lines are controlled to allow for switching only when both currents are present at an MTJ cell at the same time and the sum of applied magnetic fields H(EA) and H(HA) falls outside the astroid curve.

In various field-switching MRAM device designs, one of the two orthogonal conductor lines, such as the bit line, is used to provide a bi-directional switching field to switch the magnetization of the MTJ cell while the other conductor line, such as the word line, is used to supply a uni-direction constant current for the switching so that the total magnetic field of the two magnetic fields from the word and bit lines exceeds the switching threshold on the astroid curve in FIG. 3. The bit lines can be oriented perpendicular to the long axis or easy axis of the MTJ memory cells to produce a magnetic field along the easy axis. This layout with one conductor line perpendicular to the long axis of the elongated MTJ cell occupies unnecessarily large area due to the CMOS layout footprint for each unit cell. In addition, as discussed above, the “off-plug” configuration in many field-switching MTJ devices further enlarges the minimum size of each unit cell.

In the field-switching MTJ device shown in FIG. 2, the bit line is oriented to be perpendicular to the elongated axis of the MTJ cell and is used to produce the primary magnetic field for switching the free layer in writing. The dimension of each feature or spacing between two features must be at least the critical dimension F of the technology node used in fabrication. The presence of both orthogonal word and bit lines for writing and the use of the off-plug configuration in each unit cell impose a lower limit to the unit cell size. In a design with one transistor per one MTJ cell (1T/1MTJ) in each unit cell, the minimum area of the unit cell is estimated to be about 30 to 35F² for the example shown in FIG. 2. For the 90-nm technology node, for example, each unit cell is about 2.4×10⁵ nm² to 2.8×10⁵ nm². This unit cell is relatively large and can limit the applications of memory chips due to the large size and the cost.

An MTJ device with an MTJ cell array based on the spin-transfer switching for recording bits in the cells do not require the above two orthogonal conductor lines in each MTJ cell for writing the bit. A single conductor line can be electrically coupled to the MTJ cell to supply a write current that flows through the tunnel junction in the MTJ cell to switch the free layer without an external magnetic field generated by two orthogonal conductor lines. The switching by the spin torque transfer arises from the spin-dependent electron transport properties of ferromagnetic-normal metal multilayers. When a spin-polarized current traverses a magnetic multilayer structure in a direction perpendicular to the layers, the spin angular momentum of electrons incident on a ferromagnetic layer interacts with magnetic moments of the ferromagnetic layer near the interface between the ferromagnetic and normal-metal layers. Through this interaction, the electrons transfer a portion of their angular momentum to the ferromagnetic layer. As a result, a spin-polarized current can switch the magnetization direction of the ferromagnetic layer if the current density is sufficiently high, e.g., approximately 10⁶-10⁸ A/cm² in some MTJ cells.

Therefore, an MTJ device with an MTJ cell array based on the spin-transfer switching for recording bits in the cells can eliminate the two orthogonal conductor lines in each MTJ cell in the field-switching devices and eliminates the need for spatially separating the MTJ from the underlying metal plug as part of the conductive path for directing a current through the MTJ. In addition, because the switching is caused by the write electric current flowing through the MTJ rather than the external magnetic field at the MTJ, the direction of the conductor line that supplies the write current can be in any orientation and may be chosen in way to minimize the size of the MTJ cell without affecting the switching operation. The examples for MTJ devices based on the spin-transfer switching explore these and other aspects of spin-transfer switching MTJ devices and provide an on-plug MTJ design that directly places each MTJ cell on top of a respective metal plug to minimize the size of each unit cell and thus increase the cell density. This on-plug design simplifies the unit cell design and eliminates the local interconnecting conductor between the MTJ cell and the metal plug in various field-switching MTJ devices based on the off-plug design. Therefore, the minimum size of each unit cell can be reduced for a given technology node to achieve higher unit cell density than what is possible in various field-switching MTJ devices based on the off-plug design.

In such on-plug MTJ devices based on the spin-transfer switching, a single conductor line, e.g., the bit line, is sufficient for supplying the write current for switching each MTJ cell and can be oriented in any direction relative to the long axis of the MTJ cell as the designer desires. In one implementation, the single bit line for each cell may be oriented to be parallel to the long axis of the MTJ cells in order to further reduce the size of each unit cell in an on-plug design.

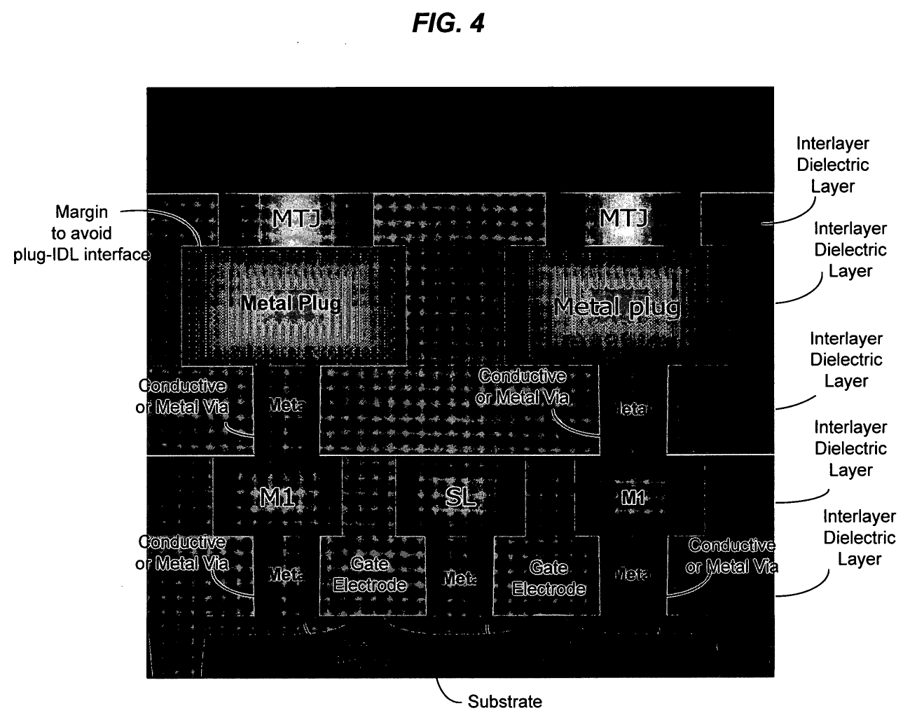

FIG. 4 illustrates one exemplary layout of an on-plug MTJ device with an array of unit cells where the MTJ cell in each unit cell is fabricated directly on top of a metal via plug on the substrate. A conductive via, e.g., a metal via, is formed over the substrate and is vertically extended substantially perpendicular to the substrate to electrically connect two different metal layers separated by interlayer dielectric material. A metal plug is formed on the conductive via and the MTJ cell is directly formed on top the metal plug and in directly electrical contact with the metal plug. A metal buffer layer may be formed between the bottom of the MTJ cell and the top of the metal plug. This design eliminates the spacing between the metal plug and the MTJ cell in each unit cell and the interconnecting conductor that connects the MTJ cell to the metal plug. A metal line is formed on top of and in contact with a series of MTJ cells as a bit line for the MTJ cells to supply the write current to each MTJ cell. Other circuit elements for each unit cell such as the gate electrodes are also shown. The lateral dimension of each MTJ cell is shown to be less than that of the underlying metal plug in this specific example and can be equal to or less than that of the underling metal plug in other implementations. The conductive metal vias and interlayer dielectric (ILD) layers are illustrated in a 4-layer structure as an example where the first metal layer provides the source conductor line (SL) and other conductors for each MTJ cell circuit. On top of each metal plug, an MTJ cell is fabricated in direct contact with the metal plug. A second metal layer is then formed over the MTJ layer to provide the bit lines for the MTJ array. In this example, each source conductor line is shown to be perpendicular to the bit line. In other implementations, the source conductor line can be parallel to the bit line.

FIG. 5 illustrates a portion of a device with an array of unit cells with on-plug MTJ cells based on the spin torque transfer switching where the bit lines are oriented to be parallel to the long axis of the MTJ cells to better match the CMOS layout underneath the unit cells and to reduce the unit cell size. Notably, in each unit cell, the metal plug and the MTJ cell are not only laterally separated from each other and now overlap to reduce the footprint of each unit cell. In this example, the bit line on the unit cell area is about 12F² in area for the on-plug MTJ cells when the parameters, including materials and processing, are optimized. In comparison with the unit cell size of 30 to 35F² in the off-plug field switching MTJ design in FIG. 2, the saving in the chip space is significant. Notably, the footprint of each MTJ cell is smaller than the footprint of the underlying metal plug by a margin due to a limitation imposed by a particular fabrication process, e.g., about one half of the critical dimension F of the technology node used in fabrication as illustrated in FIG. 5. As described in later sections of this application, a different fabrication process can be used to eliminate this difference in the footprint size between the MTJ cell and the metal plug so that the footprint of the metal plug can be equal to or even less than the footprint of the MTJ cell to further reduce the unit cell area for the on-plug design in FIG. 5 to 8F² or 6F².

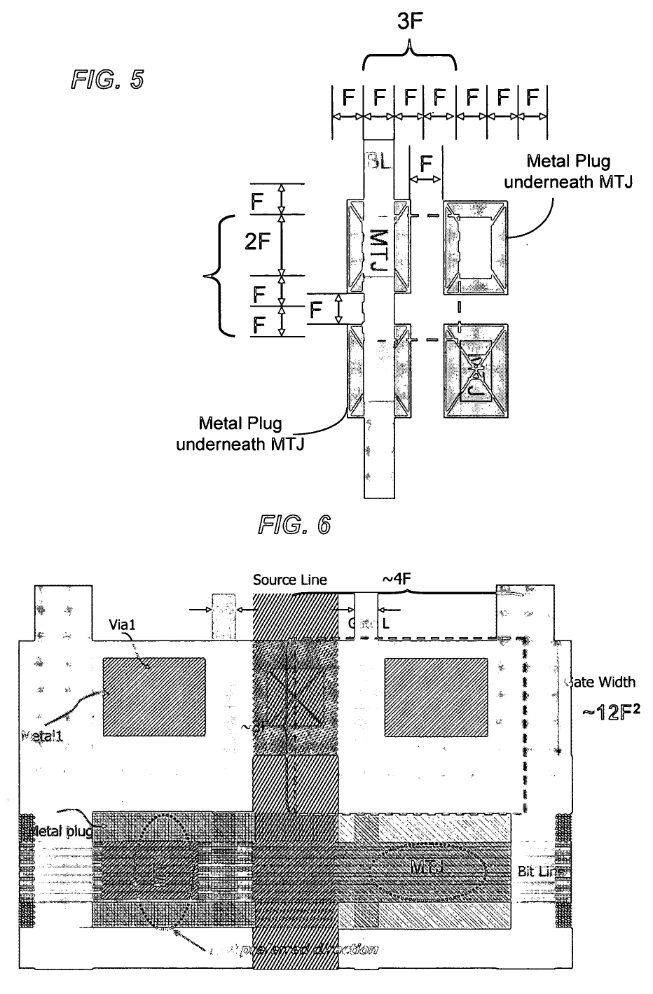

FIG. 6 compares the layout of the unit cells that use two different relative orientations of MTJ cells relative to the bit lines using the on-plug design for the spin torque transfer switching. When the long axis of the MTJ cell is aligned along the bit line, the unit cell size is reduced in comparison with the alternative configuration where the long axis of the MTJ cell is perpendicular to the bit line.

In fabrication of the above MTJ and other MTJ devices based on the on-plug MTJ design, one technical issue is to form a substantially flat surface over a region with different materials displaced from each other parallel to the flat surface. One example for such a situation is a flat surface over an inter level dielectric (ILD) layer that has at least one embedded metal region such as a metal plug. In fabrication of such a flat surface, the ILD layer and the embedded metal plug are first formed. Next, the ILD layer and the embedded metal plug are polished at the same time by a polishing process such as the chemical mechanical polishing (CMP) to form the flat surface. On top of each polished metal plug, the MTJ is then fabricated.

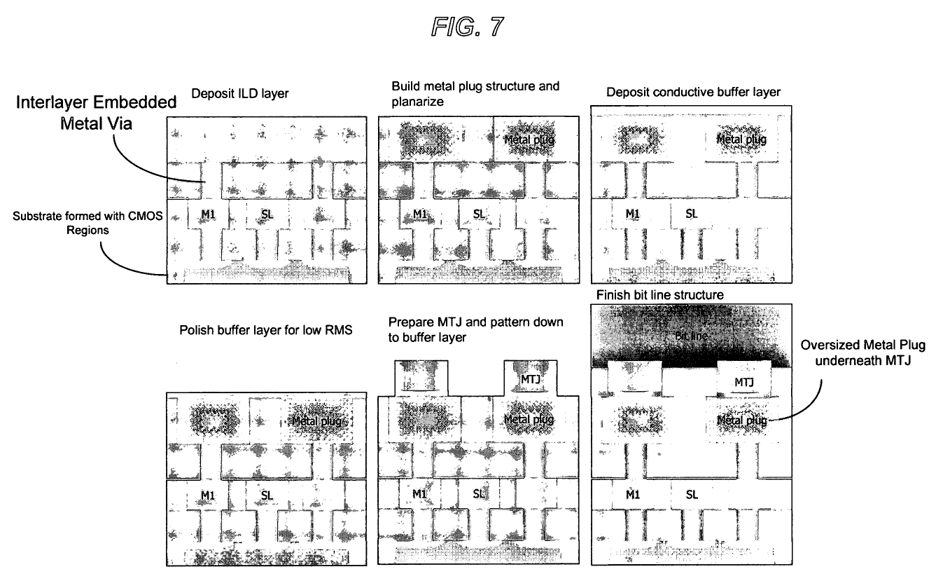

Various fabrication processes may be used to fabricate the on-plug MTJ devices described in this application. FIG. 7 illustrates one example of a fabrication process for fabricating MTJ cells located on top of corresponding metal plugs. A substrate is first processed to form CMOS regions for transistors and other CMOS circuit elements for the MTJ device. Next, metal via structures, a first metal layer (Ml) patterned to form the source conductor line (SL), the word line, and other conductive structures, and additional metal via structures above the first metal layer. Subsequently, the top ILD layer is patterned to include metal plugs embedded in the top ILD layer. The top ILD layer and the metal plug are then planarized by, e.g., chemical mechanical polishing (CMP), to form a flat surface that exposes the metal plugs. On top of the planarized surface, a conductive buffer layer is deposited to cover the flat surface including the exposed top surfaces of the metal plugs and the top surfaces of the top ILD layer. MTJ layers are formed on top of the conductive buffer layer. After patterning the MTJ layers and the buffer layer to form the individual MTJ cells, a third metal layer is formed and patterned to form the bit lines. The conductive buffer layer underneath the MTJs may be made of a variety of materials including tungsten, NiFeCr, Cr, TiW, TiN, Cu, and so on. The conductive buffer layer thickness may be from 100 Å to 5000 Å. The polishing of the conductive buffer layer may be performed with small slurry particles at a lower lapping rate and a slower material removal rate as compared to a standard CMP process.

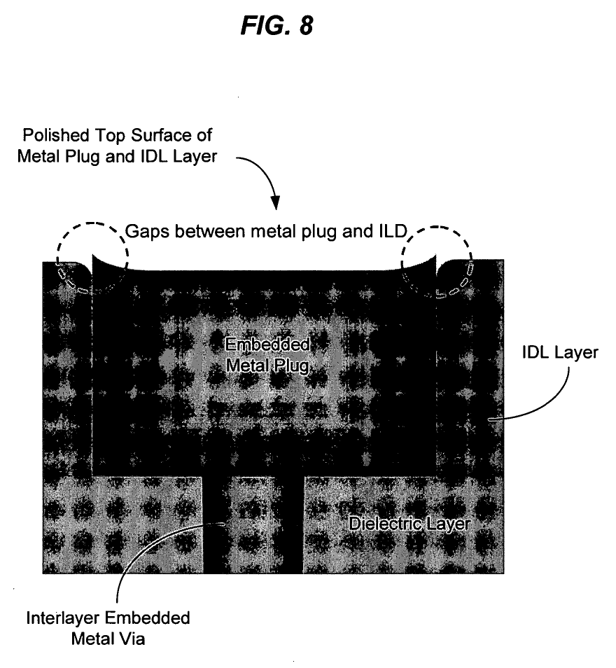

In the above process, the metal plugs and the ILD layer are planarized at the same time by the same CMP process. However, the metal material for the metal plugs and the dielectric material for the ILD material are different and thus the amounts of the removal of the metal plugs and the ILD material are different. This difference causes a gap at the interface between the metal plug and the ILD material and thus creates a top surface that is uneven at each interface. FIG. 8 illustrates the planarized surface with gaps at interfaces between the metal plugs and the ILD material.

Such gaps at the borders of metal plugs can be problematic for fabricating on-plug MTJ cells on top of the metal plugs. In the fabrication process in FIG. 7, the conductive buffer layer formed on top of the polished metal plugs and the ILD layer can conform to the surface profile of the top surfaces of the polished metal plugs and ILD layer and thus can form the bumps over the gaps at the underlying interfaces of polished metal plugs and the polished ILD layer. When the MTJ layers are formed on top of the conductive buffer layer, the MTJ layers are not flat but conform to the bumps in the conductive buffer layer.

It is well known that MTJs are sensitive to any lateral spatial variation in the thickness of the junction layers along the layers and the properties and performance of an MTJ cell, such as the TMR, interlayer coupling field and the MTJ breakdown voltage, may be significantly degraded by such lateral spatial variation. For this reason, it is desirable to locate an on-plug MTJ over an ultra-smooth surface and place the MTJ away from an interface between the metal plug and the ILD material so that the effect of an underlying gap at an interface on the MTJ cell is not significant to the MTJ film performance.

The surface on which the MTJ layers are fabricated can be characterized by the surface flatness and the surface smoothness. In some implementations of the on-plug MTJ design, the top surface of each metal plug needs to meet some threshold for the surface smoothness. For example, the top surface of each metal plug may be required to have a surface roughness less than 3 Å for the root-mean-square (RMS) value in some device designs. In addition, independent from the smoothness requirement, the top surface of each metal plug needs to meet some threshold for the surface flatness. For example, the top surface may be required to have a minimal dishing or warping to be less than 200 Å and preferably less than 100 Å. The process shown in FIG. 7, if not properly implemented, may produce gaps between the metal plugs and the ILD material that cause undesired profile variations in the MTJ layers and lead to unacceptable device performance such as device failure in TMR, resistance shorting and reliability issue.

Therefore, in implementing the fabrication process in FIG. 7, the lateral dimension or footprint of the metal plugs can be purposely designed to be larger than the MTJ cells so that each final MTJ cell is located around the center of a corresponding underlying metal plug in each unit cell and is sufficiently away from the boundary of the metal plug with the ILD layer material. Design rules for the fabrication process in FIG. 7 can be set to accommodate the size variation and photolithography overlay errors to ensure there is a sufficient spacing margin between each on-plug MTJ and the edges of the underlying metal plug. The boundary condition in design is to limit the MTJ cell size within the border of a metal plug that interfaces with the surrounding ILD material in order to avoid building the MTJ over a gap or sufficiently near a gap. The on-plug MTJs in FIG. 4 are examples that use large metal plugs and small MTJs to mitigate the gap issue in the fabrication process in FIG. 7.

In recognition of the above, an alternative fabrication process for fabricating on-plug MTJ devices is described below to avoid planarizing two different materials in forming the planarized surface on which the MTJ cells or other profile sensitive structures are built on top of the planarized surface. This alternative fabrication process essentially eliminates the cause for the gaps in the process in FIG. 7 and thus creates a smooth surface without gaps for forming MTJs. Accordingly, the requirements for making the lateral dimension of the metal plugs bigger than the MTJ cells in the process of FIG. 7 are no longer needed and a more compact unit cell can be fabricated.

In one implementation of this alternative process, a metallization process is performed to construct metal plugs embedded in an ILD layer and a metal layer integrally connected with the embedded metal plugs on top of the ILD layer to cover both the metal plugs and the ILD layer. Next, the metal layer is thinned by, e.g., CMP, to form a thin and polished metal layer on top of the ILD layer and the underlying and connected metal plugs. This thinning process is conducted without exposing the ILD layer so that only the same metal material is lapped during the CMP process. As a result, the thin and polished metal layer on top of the metal plugs and the ILD material is smooth and is free of any gaps caused by polishing the metal and the ILD material at the same time. Next, the MTJ layers are deposited on top of the entire thin and polished metal layer. The MTJ layers and the underlying metal layer on top of the ILD and metal plugs are subsequently patterned to form separated MTJ cells that are directly located on top of the metal plugs, respectively. The bit line and other structures are also formed.

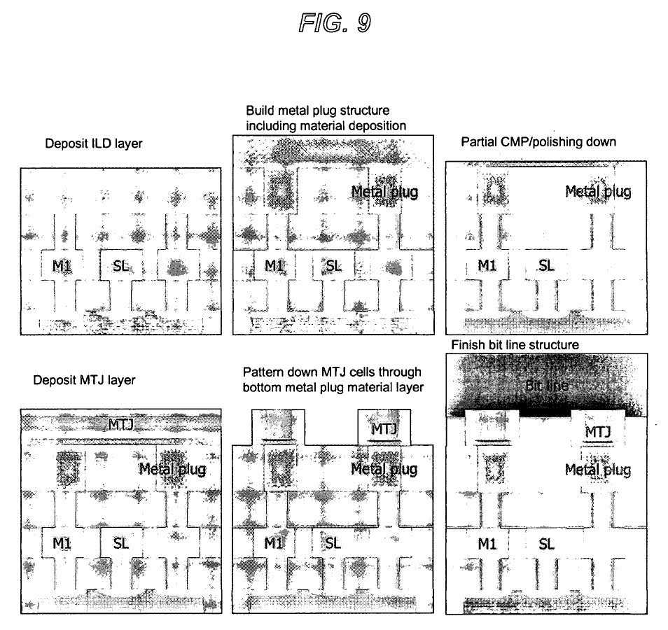

FIG. 9 shows an example of the above alternative fabrication process by using a partial CMP polishing of a metal layer over an ILD layer and metal plugs embedded in the ILD layer. This fabrication process eliminates the polishing of two different materials, i.e., the metal plug and surrounding ILD material, in forming the surface on which the MTJ cells are formed on top of the metal plugs. Therefore, there is no gap formed between an interface between the metal plug and the ILD material in the process. As a result, this process eases the design rules and allows for a reduced size of the metal plug in the layout. In implementations, the lateral dimension of each metal plug can be equal to or less than each MTJ and thus can further reduce the MTJ cell size in comparison with the fabrication process in FIG. 7.

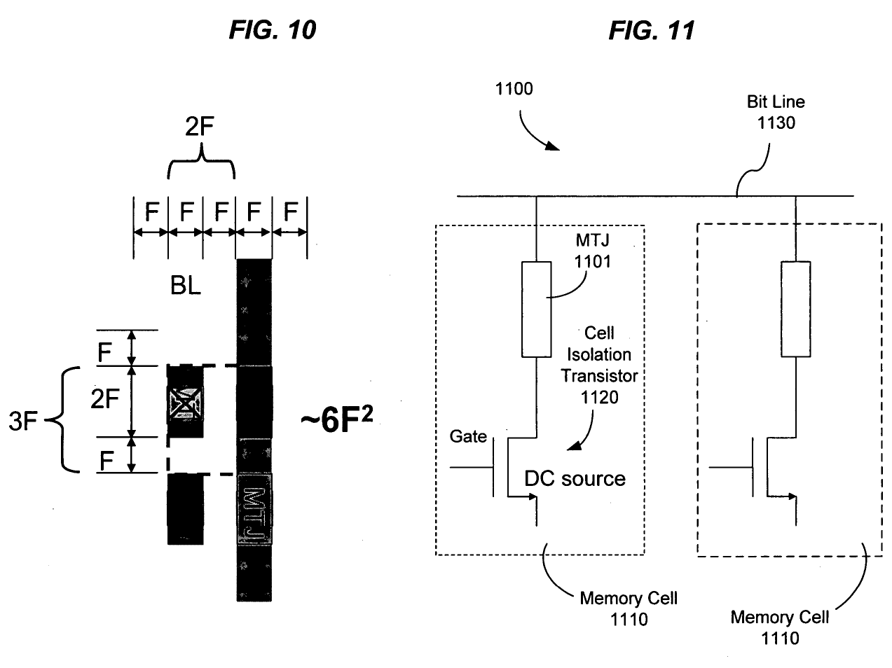

FIG. 10 shows an example of an on-plug MTJ cell array based on the fabrication process in FIG. 9 where the bit lines are oriented to be parallel to the long axis of the MTJ cells. The MTJ cell design is identical to that in FIG. 5. However, with the new design rule under the process in FIG. 9, a smaller area is used by each unit cell. While the area of the unit cell in FIG. 5 is about 12F², the area of the unit cell design in FIG. 10 is further reduced to about 6F², a reduction of a factor of 2.

FIG. 11 shows an example of a current switched spin-transfer MRAM device 1100 having an array of memory cells 1110 where an MTJ cell 1101 in each unit cell 1110 is connected to an isolation/write transistor 1120 and a bit line 1130. This design eliminates the write word line that is perpendicular to the bit line 1130 and that operates jointly with the bit line 1130 to produce a switching magnetic field as in a field-switching MTJ device shown in FIG. 2. Switching via the spin-transfer occurs when a DC current supplied by the bit line 1130 and controlled by the transistor 1120, passing through a magnetic layer of the MTJ cell 1101, becomes spin polarized and imparts a spin torque on the free layer of the MTJ cell 1101. When a sufficient spin torque is applied to the free layer, the magnetization of the free layer can be switched between two opposite directions and accordingly the MTJ cell 1101 can be switched between the parallel and antiparallel states depending on the direction of the DC current. The isolation/write transistor 1120 controls the direction and magnitude of the DC current flowing through the MTJ cell 1101. This control may be achieved by the relative voltages at the gate, source and drain of the transistor 1120. The MTJ cell 1101 may be implemented in various configurations, including the on-plug cell designs described in this application. In operation, the transistor 1120 supplies both the write current for writing data by changing the magnetic state of the free layer in the MTJ cell 1101 and the read current for reading data without changing the magnetic state of the free layer in the MTJ cell 1101. The transistor 1120 may be a COMS transistor whose diffusion regions and gate channel are formed in the substrate over which the MTJ cells are formed. This circuit design can be used for on-plug MTJ devices based on spin torque transfer described in this application. As an example, in implementing the circuit design in FIG. 11, metal vias and a metal plug formed underneath the MTJ cell in FIG. 9 can be used to electrically connect the transistor 1120 to the MTJ 1101. Only a few examples and implementations are described. One of ordinary skill in the art can readily recognize that variations, modifications and enhancements to the described examples may be made.

What is claimed is:

1. A device, comprising:
a substrate;
a conductive via formed over the substrate and vertically extended substantially perpendicular to the substrate;
a metal plug formed on top of the conductive via;
a dielectric material embedding the metal plug and exposing a top surface of the metal plug; and
a magnetic tunnel junction (MTJ) cell formed on the top surface of the metal plug.

2. The device as in claim 1, further comprising a metal buffer layer between the MTJ cell and the top surface of the metal plug.

3. The device as in claim 1, wherein the MTJ cell is elongated, and wherein the device further comprises:
a conductor line formed over the substrate and positioned to have a portion which spatially overlaps with the MTJ cell, the conductor line being electrically coupled to supply a current across the MTJ cell and through the metal plug and the conductive via.

4. The device as in claim 3, wherein the portion of the conductor line which spatially overlaps with the MTJ cell is parallel to an elongated direction of the MTJ cell.

5. The device as in claim 1, wherein the MTJ cell has a footprint less than a footprint of the metal plug and is position near a center of the top surface of the metal plug and is away from an edge of the metal plug.

6. The device as in claim 1, wherein the MTJ cell has a footprint greater than a footprint of the metal plug.

7. The device as in claim 1, wherein the MTJ cell has a footprint approximately equal to a footprint of the metal plug.

8. The device as in claim 1, further comprising:
a conductor line formed over the substrate and electrically coupled to the MTJ cell to supply a current across the MTJ cell and through the metal plug and the conductive via.

9. The device as in claim 8, further comprising:
a control circuit to control the current to the MTJ cell from the conductor line to change the magnetization direction of the free ferromagnetic layer of the MTJ cell via spin torque transfer.

10. The device as in claim 1, wherein the MTJ cell comprises:
a free ferromagnetic layer having a magnetization direction that is changeable between a first direction and a second substantially opposite direction,
a fixed ferromagnetic layer having a magnetization direction fixed along substantially the first direction, and
an insulator barrier layer formed between the free and fixed ferromagnetic layers to effectuate tunneling of electrons between the free and fixed ferromagnetic layers.

11. A device, comprising:
a substrate;
a magnetic tunnel junction (MTJ) cell formed over the substrate and comprising a free ferromagnetic layer having a magnetization direction that is changeable between a first direction and a second substantially opposite direction, a fixed ferromagnetic layer having a magnetization direction fixed along substantially the first direction, and an insulator barrier layer formed between the free and fixed ferromagnetic layers to effectuate tunneling of electrons between the free and fixed ferromagnetic layers, wherein the magnetic tunnel junction cell is shaped to be elongated along the first direction;
a conductor line formed over the substrate and positioned to have a portion which spatially overlaps with the MTJ cell and is parallel to the first direction of the MTJ cell and is electrically coupled to supply a current across the MTJ cell; and
a control circuit to control the current to the MTJ cell from the conductor line to change the magnetization direction of the free ferromagnetic layer of the MTJ cell via spin torque transfer.

12. A device as in claim 11, further comprising:
a conductive via formed over the substrate and vertically extended substantially perpendicular to the substrate;
a metal plug formed on top of the conductive via; and
a dielectric material embedding the metal plug and exposing a top surface of the metal plug,
wherein the MTJ cell is formed over the top surface of the metal plug.

13. The device as in claim 11, further comprising a metal plug formed over the substrate, wherein the MTJ cell is formed on top of and is connected to the metal plug.

14. The device as in claim 13, wherein the metal plug has a footprint that is less than a footprint of the MTJ cell.

15. A method, comprising:
forming a dielectric layer over a substrate;
subsequently forming a contiguous metal structure to include at least one metal plug which is embedded in the dielectric layer and a metal layer which is atop and covers a top surface of the dielectric layer;
partially removing the metal layer of the contiguous metal structure to leave a remaining metal layer of the metal layer that is atop and covers the top surface of the dielectric layer without exposing the dielectric layer;
forming magnetic tunnel junction (MTJ) layers on the remaining metal layer; and
patterning the MTJ layers to form at least one MTJ cell on top of the remaining metal layer.

16. The method as in claim 15, wherein the MTJ cell is directly positioned above the metal plug, and the remaining metal layer is patterned to confirm to a footprint of the MTJ cell.

17. The method as in claim 16, further comprising:
controlling the patterning of the MTJ layers and the remaining metal layer to make a footprint of the MTJ cell and the remaining metal layer underneath the MTJ cell to be not less than a footprint of the metal plug.

18. The method as in claim 15, further comprising controlling the partial removal of the metal layer of the contiguous metal structure to keep a surface warping less than 200 Å and a surface roughness less than 3 Å for the root-mean-square (RMS) value.

19. A method, comprising:
forming a dielectric layer over a substrate;
subsequently forming at least one metal plug embedded in the dielectric layer;
polishing the dielectric layer and the metal plug embedded in the dielectric layer to form a polished surface which exposes a top surface of the metal plug;
forming a conductive buffer layer over the polished surface to cover the dielectric layer and the metal plug;
forming magnetic tunnel junction (MTJ) layers on the conductive buffer layer; and
patterning the MTJ layers to form at least one MTJ cell on the conductive buffer layer and on top of the metal plug.

20. The method as in claim 19, further comprising:
controlling the patterning of the MTJ cell to make a footprint of the MTJ cell less than a footprint of the metal plug and to place the MTJ cell near a center of the top surface of the metal plug and is away from an edge of the metal plug.
